(19) United States
(12) Patent Application Publication
(10) Pub. No.: US 2012/0129442 A1
(43) Pub. Date: May 24, 2012

(54) CONTAINER DATA CENTER

(75) Inventor: CHAO-KE WEI, Tu-Cheng (TW)

(73) Assignee: HON HAI PRECISION INDUSTRY CO., LTD., Tu-Cheng (TW)

(21) Appl. No.: 12/978,619

(22) Filed: Dec. 26, 2010

(30) Foreign Application Priority Data
Nov. 19, 2010 (TW) 99140082

(51) Int. Cl. H05K 5/02

(52) U.S. Cl. 454/184

(57) ABSTRACT

A container data center includes a container, a number of server systems installed in the container, a heat dissipating system, and two static air purifier devices. Two air inlets and two air outlets are defined in the container. The static air purifier devices are respectively attached to sidewalls of the container, and communicating with the air inlets of the container. The heat dissipating system drives air outside the container to flow into the container through the air inlets after flowing through the static air purifiers to be filtered of dust, and exhausts hot air generated by the servers through the outlets of the container.

### BACKGROUND

1. Technical Field

The present disclosure relates to container data centers, and more particularly, to a container data center with an air purifier.

2. Description of Related Art

At present, racks of servers are arranged in a container, together with relevant equipment, to form a portable container data center, which is employed in all kinds of locations. However, when the container data center is employed in a very dusty environment, too much dust may enter the container and cause problems.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a schematic view of an exemplary embodiment of a container data center, the container data center includes an air purifier.

FIG. 2 is a schematic view of an air purifier used in another exemplary embodiment of a container data center.

### DETAILED DESCRIPTION

The present disclosure, including the accompanying drawings, is illustrated by way of examples and not by way of limitation. It should be noted that references to “an” or “one” embodiment in this disclosure are not necessarily to the same embodiment, and such references mean at least one.

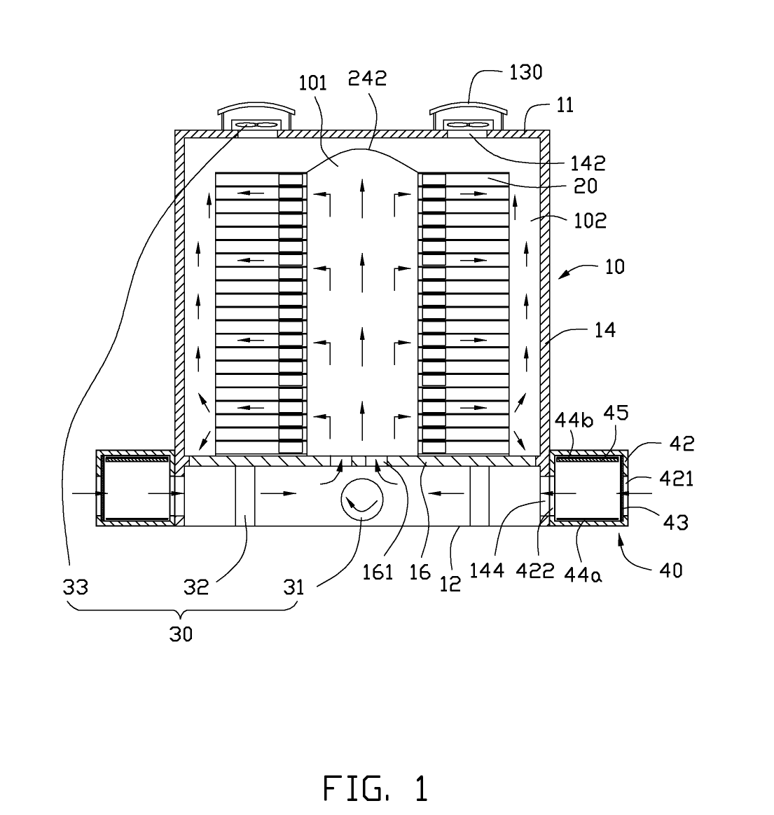

Referring to FIG. 1, an exemplary embodiment of a container data center includes a mobile container 10, a plurality of server systems 20 installed in the container 10, a heat dissipating system 30, and two static air purifiers 40.

The container 10 includes a top wall 11, a bottom wall 12 opposite to the top wall 11, two sidewalls 14 substantially perpendicularly connected between opposite sides of the top wall 11 and bottom wall 12, and a raised floor 16 parallel to and close to the bottom wall 12 of the container 10. Each of the sidewalls 14 defines an air inlet 144, arranged between the raised floor 16 and the bottom wall 12. The top wall 11 defines two air outlets 142. In one embodiment, two rain shields 130 are mounted to the top wall 11 to respectively cover the air outlets 142, thereby preventing water entering the container 10 through the air outlets 142. The server systems 20 are arranged in two parallel rows and supported on the raised floor 16. A heat shield 242 is provided to connect tops of the two rows of server systems 20.

In the container 10, there are a cold aisle 101 defined among the server systems 20, the heat shield 242, and the raised floor 16, and a hot aisle 102 defined among the sidewalls 14 of the container 10, the server systems 20, the heat shield 242, and the raised floor 16. The raised floor 16 defines a plurality of openings 161 communicating with the hot aisle 101.

The heat dissipating system 30 includes an air input device 31 installed between the bottom wall 12 and the raised floor 16, two heat exchangers 32 positioned at opposite sides of the air input device 31, respectively adjacent to the air inlets 144 of the container 10, and two air exhaust devices 33 respectively attached to the top wall 11 of the container 10, aligned with the air outlets 142.

The static air purifiers 40 are respectively attached to outer surfaces of the sidewalls 14 of the container 10. Each of the static air purifiers 40 includes a chamber 42, a filter 43 mounted in the chamber 42, an anode plate 44a, a cathode plate 44b, and a dust collector 45. The chamber 42 defines an air intake 421 opposite to the sidewall 14, and an air passage 422 adjacent to the sidewall 14. The air passage 422 is aligned with the air inlet 144 of the sidewall 14 of the container 10. The filter 43 covers the air intake 421. The anode plate 44a and the cathode plate 44b are positioned between the filter 43 and the air passage 422, opposite to each other. The dust collector 45 is attached to the cathode plate 44b, between the anode plate 44a and the cathode plate 44b.

In use, air outside the container 10 is driven to flow through the static air purifiers 40, then flow into the container 10 through the air intakes 14 by the air input devices 30. The air flows through the heat exchangers 32 to be cooled, and then the cooled air is guided into the cold aisle 101. The server systems 20 draw cooled air from the cold aisle 101, and dissipate hot air into the hot aisle 102. The hot air in the hot aisle 102 flows upwards and is exhausted out of the container 10 through the air outlets 142 by the air exhausting devices 33. When the ambient temperature of the container 10 is low enough, the heat exchangers 32 may be shut down for power conservation.

To remove dust from the air entering the container 10, each of the static air purifiers 40 is powered on to form an electric field between the anode plate 44a and the cathode plate 44b, thereby generating an amount of positive and negative ions suspended in the electric field. The air flows into the chamber 42 of the static air purifiers 40 through the entrance 421, flows through the filter 43 and the electric field in sequence, and flows out of the chamber 42 through the air passage 422. When the air flows through the filter 43, larger dust particles are caught by the filter 43. When the air flows through the electric field, smaller dust particles in the air are charged by combining with the positive or negative ions. The dust particles combined with positive ions move toward the cathode plate 44b under effect of the electric field, and are collected by the dust collector 45. Therefore, the air is filtered of dust before entering the container 10. It can be understood that if the dust collector 45 is attached to the anode plate 44a, the dust particles combining with the negative ions will move towards the anode plate 44a and be accumulated on the dust collector 45. In one embodiment, the filter 43 and the dust collector 45 can be detached from the chamber 42 and cleaned for reuse.

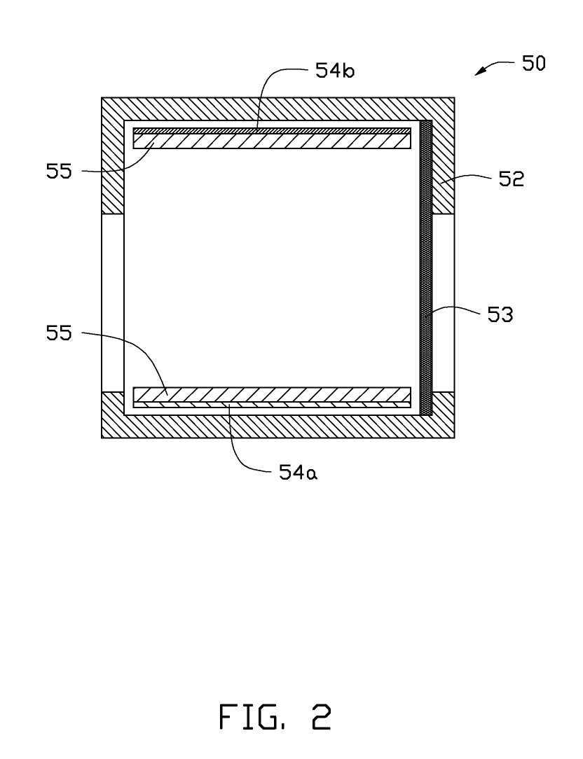

In another embodiment, each of the static air purifiers 40 is replaced with a static air purifier 50 shown in FIG. 2. The static air purifier 50 includes a chamber 52, a filter 53 mounted in the chamber 52, an anode plate 54a, a cathode plate 54b, and two dust collectors 55 respectively attached to the anode plate 54a and the cathode plates 54b. Therefore, in operation of the static air purifier 50, when the air flows through the electric field formed between the anode and cathode plates 54a and 54b, dust particles in the air are charged by combining with positive or negative ions in the electric field, then the charged dust particles move towards the anode plate 54a and the cathode plate 54b to be respectively accumulated on the dust collectors 55.

It is to be understood, however, that even though numerous characteristics and advantages have been set forth in the foregoing description of embodiments, together with details of the structures and functions of the embodiments, the present disclosure is illustrative only and changes may be made in detail, especially in matters of shape, size, and arrangement of parts within the principles of the present disclosure to the full extent indicated by the broad general meaning of the terms in which the appended claims are expressed.

What is claimed is:

1. A container data center comprising:
a mobile container defines an air inlet and an air outlet,
a plurality of server systems installed in the container;
a heat dissipating system to drive air outside the container to flow into the container through the air inlet to cool the server systems, and exhaust hot air dissipated by the server systems out of the container through the air outlet; and
an static air purifier comprising a chamber attached to the container and communicating with the air inlet of the container, an anode plate and a cathode plate installed in the chamber to form an electric field between the anode and the cathode plates, and a dust collector selectively attached to the anode plate or the cathode plate, wherein the air flows through the static air purifier before flowing into the container, dust particles in the air are charged and move under effect of the electric field to be collected on the dust collector, in response to the air flowing through the electric field.

2. The container data center of claim 1, wherein the static air purifier further comprises a filter installed in the chamber, wherein the chamber defines an air intake and an air passage aligned with the air inlet of the container, the air flows into the chamber through the air intake and flows out of the chamber through the air passage, the filter covers the air intake of the chamber.

3. The container data center of claim 2, wherein the anode and the cathode plates are positioned between the air intake and the air passage of the chamber.

4. The container data center of claim 2, wherein the container comprises a top wall, a bottom wall opposite to the top wall, and two sidewalls connected between the top wall and the bottom wall, the air inlet of the container is defined in one of the sidewalls adjacent to the bottom wall, the air outlet of the container is defined in the top wall of the container.

5. The container data center of claim 4, wherein the container comprises a raised floor parallel to and close to the bottom wall of the container, the air inlet of the container is located between the raised floor and the bottom wall.

6. The container data center of claim 5, wherein the heat dissipating system comprises an air input device located between the bottom wall and the raised floor, a heat exchanger located between the air inlet of the container and the air input device, and an air exhausting device attached to the top wall of the container and aligned with the air outlet.

7. The container data center of claim 4, wherein a rain shield is mounted to the top wall of the container to cover the air outlet, thereby preventing water entering the container through the air outlet.

8. The container data center of claim 2, wherein the filter and the dust collector are detachably mounted to the chamber.

9. The container data center of claim 1, wherein the air purifier further comprises a second dust collector attached to the other one of the anode plate and the cathode plate.
